(19) United States
(12) Patent Application Publication
(10) Pub. No.: US 2025/0286521 A1
(43) Pub. Date: Sep. 11, 2025

(54) LIMITING PEAK CURRENT IN A CONVERGED DEVICE

(71) Applicant: MOTOROLA SOLUTIONS, INC., Chicago, IL (US)

(72) Inventors: Oren Peled, Ramat-Gan (IL); Haim Caspo, Petach Tikva (IL); Isaac Edry, Ramat-Gan (IL); Lionid Kodner, Modi'in-Maccabim-Re'ut (IL)

(21) Appl. No.: 18/598,702

(22) Filed: Mar. 7, 2024

(51) Int. Cl. H03F 3/24; H04B 1/04

(52) U.S. Cl. CPC H03F 3/245; H04B 1/0475; H04B 1/0483; H03F 2200/451; H04B 2001/0408

(57) ABSTRACT

Examples provide a converged communication device including a first radio frequency (RF) transmitter system configured to transmit signals according to a first communication protocol, and a second RF transmitter system configured to transmit signals according to a second communication protocol. An attenuator operable in an active mode and a bypass mode is configured to receive an RF signal generated by a processor of the second RF transmitter system and selectively attenuate the RF signal. In the bypass mode, the attenuator outputs the RF signal to an RF power amplifier (RFPA) of the second transmitter system without attenuation. In the active mode, the attenuator attenuates the RF signal and outputs an attenuated RF signal to the RFPA. An attenuator control circuit controls the attenuator for operation in the active mode or the bypass mode based on state information received from the first RF transmitter system and/or the second RF transmitter system.

### BACKGROUND

Wireless communication devices transfer information using various communication protocols and techniques. A wireless communication device may be a converged device capable of providing communications via multiple communication protocols. Such protocols may include, for example, cellular communication protocols, for example long-term evolution (LTE), land mobile radio (LMR) protocols, or other wireless communication protocols.

### BRIEF DESCRIPTION OF THE DRAWINGS

FIG. 1 illustrates a converged communication device, according to some examples.

FIG. 2 illustrates a control system for a converged communication device, according to some examples.

FIG. 3 illustrates a method for controlling operation of a converged communication device, according to some examples.

Skilled artisans will appreciate that elements in the figures are illustrated for simplicity and clarity and have not necessarily been drawn to scale. For example, the dimensions of some of the elements in the figures may be exaggerated relative to other elements to help improve understanding of examples of the present disclosure.

The system, apparatus, and method components have been represented where appropriate by conventional symbols in the drawings, showing only those specific details that are pertinent to understanding the examples of the present disclosure so as not to obscure the disclosure with details that will be readily apparent to those of ordinary skill in the art having the benefit of the description herein.

### DETAILED DESCRIPTION

Converged wireless communication devices, otherwise referred to herein as converged devices, are devices capable of communicating within multiple communication systems implementing different communication protocols. In some instances, converged devices include, in essence, two radios—a land mobile radio (LMR) and a broadband radio—for communicating in both a LMR communication system and a broadband communication system (e.g., a long term evolution (LTE) communication system). While LMR and LTE are provided as two primary examples throughout the disclosure, other converged device may be configured to implement different communication protocols, for example, the Project 25 (P25) standard defined by the Association of Public Safety Communications Officials International (APCO), the TETRA standard defined by the European Telecommunication Standards Institute (ETSI), the Digital Private Mobile Radio (dPMR) standard also defined by the ETSI, the Digital Mobile Radio (DMR) standard also defined by the ESI, LTE-Advanced or LTE-Advanced Pro compliant with, for example, the 3GPP TS 36 specification series, or the 5G (including a network architecture compliant with, for example, the 3GPP TS 23 specification series and a new radio (NR) air interface compliant with the 3GPP TS 38 specification series) standard, among other possibilities.

Converged radio devices that simultaneously perform transmissions using two different communication protocols, for example LMR and LTE, may encounter conditions causing high current drain from the battery. Traditional methods for reducing high current drain in converged devices may rely on reducing transmission power after initially transmitting at a peak power level or measuring current from the device's battery, which causes undesirable current drain. Other methods may include limiting an overall transmission power level regardless of transmission type, which may be undesirable for user that prefer not to limit transmission power level for a certain type of communication protocol. Thus, there is a need for a system and method to limit peak current in a converged device by selectively limiting transmission power level according to operating conditions of the converged device.

One example provides a converged communication device including a first radio frequency (RF) transmitter system configured to transmit signals according to a first communication protocol, the first RF transmitter system including a first RF power amplifier (RFPA) and a first electronic processor; a second RF transmitter system configured to transmit signals according to a second communication protocol different from the first communication protocol, the second RF transmitter system including a second RF power amplifier (RFPA) and a second electronic processor; an attenuator operable in at least an active mode and a bypass mode and configured to receive an RF signal generated by the second electronic processor, in the bypass mode, provide the RF signal generated by the second electronic processor to the second RFPA, and in the active mode, attenuate the RF signal generated by the second electronic processor and provide an attenuated RF signal to the second RFPA; and an attenuator control circuit configured to selectively control the attenuator for operation in the active mode or the bypass mode based on state information received from the first RF transmitter system and/or the second RF transmitter system.

In some aspects, attenuation of the RF signal generated by the second RF transmitter system limits a peak current of the converged communication device during simultaneous transmission of the attenuated RF signal and a different RF signal transmitted by the first RF transmitter system.

In some aspects, the attenuator comprises a variable attenuator, and the attenuation control circuit is configured to select an attenuation value for attenuating the RF signal generated by the second electronic processor and control the attenuator to attenuate the RF signal according to the attenuation value.

In some aspects, the attenuation control circuit is configured to select the attenuation value such that the second RF transmitter system transmits the attenuated RF signal at a predetermined decibel milliwatt (dBm) level.

In some aspects, the state information includes an indication of whether the first RF transmitter has an active transmission, and the attenuation control circuit is configured to control the attenuator for operation in the bypass mode in response to determining, based on the state information, that the first RF transmitter does not have an active transmission.

In some aspects, the state information further includes an indication of high transmission power level of the first transmitter system, and the attenuation control circuit is configured to control the attenuator for operation in the active mode in response to determining, based on the state information, that the first RF transmitter has an active transmission and that the transmission power level of the first RF transmitter system is greater than a first threshold.

In some aspects, the transmission power level of the first RF transmitter system is derived from coverage information associated with the first RF transmitter system.

In some aspects, the first threshold corresponds to a transmission power level at an edge of a coverage area for transmitting signals according to first communication protocol.

In some aspects, the attenuation control circuit is configured to control the attenuator for operation in the bypass mode in response to determining, based on the state information, that the transmission power level of the first RF transmitter system is not greater than the first threshold.

In some aspects, the state information further includes an indication of high transmission power level of the second RF transmitter, and the attenuation value is based on a difference between the transmission power level of the second RF transmitter system and the predetermined dBm level.

In some aspects, the transmission power level of the second RF transmitter is dependent on a proximity to a base station operating according to the second communication protocol.

In some aspects, the attenuation control circuit is configured to determine the transmission power level of the second RF transmitter system by sampling a data line connected between the second electronic processor and the second RFPA.

In some aspects, the attenuation control circuit is comprised of programmable hardware.

In some aspects, the first communication protocol is a land mobile radio (LMR) communication protocol.

In some aspects, the second communication protocol is a wireless broadband communication protocol.

Another example provides a method for controlling a converged communication device having a first radio frequency (RF) transmitter system configured to transmit signals according to a first communication protocol and a second RF transmitter system configured to transmit signals according to a second communication protocol different from the first communication protocol. The method includes selectively controlling, with an attenuator control circuit, an attenuator for operation in at least one of an active mode or a bypass mode based on state information received from the first RF transmitter system and the second RF transmitter system; receiving, with the attenuator, an RF signal generated by an electronic processor included in the second RF transmitter system; providing, with the attenuator in the bypass mode, the RF signal generated by the electronic processor to an RF power amplifier (RFPA) included in the second RF transmitter system; attenuating, with the attenuator in the active mode, the RF signal generated by the electronic processor; and providing an attenuated RF signal to the RFPA.

In some aspects, attenuation of the RF signal generated by the second RF transmitter system limits a peak current of the converged communication device during simultaneous transmission of the attenuated RF signal and a different RF signal transmitted by the first RF transmitter system.

In some aspects, the attenuator comprises a variable attenuator, and the method further includes: selecting, with the attenuator control circuit, an attenuation value for attenuating the RF signal generated by the electronic processor; and controlling the attenuator to attenuate the RF signal according to the attenuation value.

In some aspects, the attenuation value is selected such that the second RF transmitter system transmits the attenuated RF signal at a predetermined decibel milliwatt (dBm) level.

In some aspects, the state information includes an indication of whether the first RF transmitter has an active transmission, and the method further includes: controlling, with the attenuation control circuit, the attenuator for operation in the bypass mode in response to determining, based on the state information, that the first RF transmitter does not have an active transmission.

Examples are herein described with reference to flowchart illustrations and/or block diagrams of methods, apparatus (systems) and computer program products according to examples. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a special purpose and unique machine, such that the instructions, which execute via the processor of the computer or other programmable data processing apparatus, create means for implementing the functions/acts specified in the flowchart and/or block diagram block or blocks. The methods and processes set forth herein need not, in some examples, be performed in the exact sequence as shown and likewise various blocks may be performed in parallel rather than in sequence. Accordingly, the elements of methods and processes are referred to herein as “blocks” rather than “steps.”

These computer program instructions may also be stored in a computer-readable memory that can direct a computer or other programmable data processing apparatus to function in a particular manner, such that the instructions stored in the computer-readable memory produce an article of manufacture including instructions which implement the function/act specified in the flowchart and/or block diagram block or blocks.

Further advantages and features consistent with this disclosure will be set forth in the following detailed description, with reference to the figures.

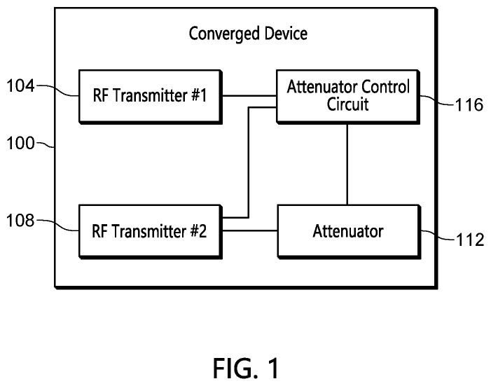

Referring now to the drawings, FIG. 1 is a block diagram illustrating a converged communication device 100, according to some examples. The converged communication device 100, otherwise referred to herein as the communication device 100, at least includes a first RF transmitter system 104 and a second RF transmitter system 108. The first RF transmitter system is configured to transmit communication signals according to a first communication protocol, and the second RF transmitter system 108 is configured to transmit communication signals according to a second communication protocol different from the first communication protocol.

In some instances, the first communication protocol is a LMR communication protocol and the second communication protocol is a broadband radio communication protocol, for example LTE. However, as described above, the first or second communication protocol are not limited to LMR and LTE.

The converged device 100 also includes an attenuator circuit 112 for selectively attenuating, or reducing a transmission power level of, communication signals generated by the second RF transmitter system 108 before the second RF transmitter system 108 transmits the communication signals. By selectively attenuating the signals generated by the second RF transmitter system 108, the converged device 100 is operable at a reduced peak current during simultaneous transmissions by the first RF transmitter system 104 and the second RF transmitter system 108.

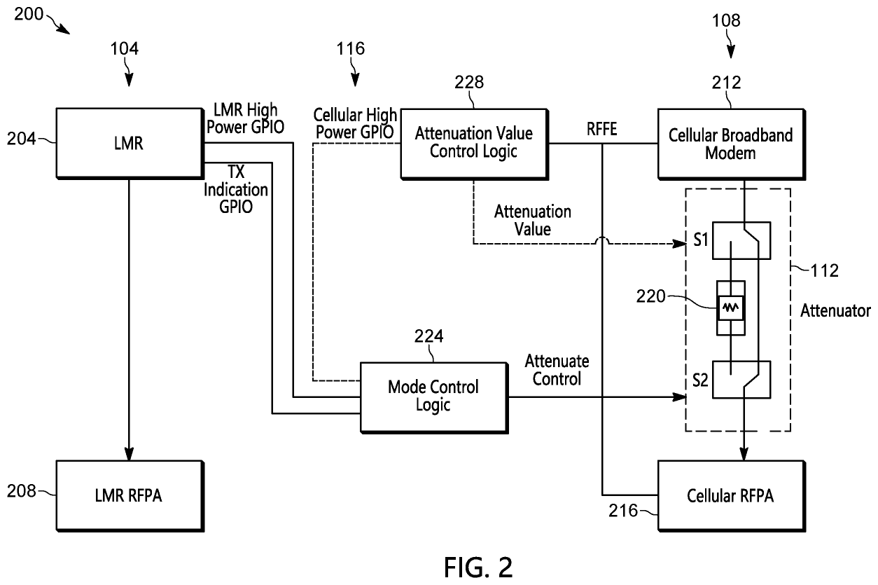

The converged device 100 also includes an attenuator control circuit 116, described in greater detail below with respect to FIG. 2, for controlling the attenuator circuit 112 to attenuate communication signals generated by the second RF transmitter system 108. The attenuator control circuit 116 controls the attenuator circuit 112 based on signals received from the first RF transmitter system 104 and the second RF transmitter system 108 indicative of operating conditions of the converged device 100 (e.g., state information respectively associated with the first RF transmitter system 104 and the second RF transmitter system 108).

It should be understood that the converged device 100 includes may include more components than those illustrated with respect to FIG. 1. For example, the converged device 100 may include one or more user interface elements, electronic controllers, and/or the like used in performing the functions described herein.

FIG. 2 illustrates a control system 200 for controlling operation of the converged communication device 100. For case of description, the first RF transmitter system 104 and the second RF transmitter system 108 are illustrated and described herein as, for example, an LMR transmitter system 104 and a broadband LTE transmitter system 108, respectively. The LMR transmitter system 104 includes a first electronic processor 204, otherwise referred to herein as an LMR processor 204, and a first RF power amplifier (RFPA) 208, otherwise referred to as an LMR RFPA 208. The LMR RFPA 208 is configured to amplify RF signals generated by the first electronic processor 204.

The LTE transmitter system 108 includes a second electronic processor 212, otherwise referred to herein as a cellular broadband modem 212, and a second RFPA 216, otherwise referred to as a cellular RFPA 216. The cellular RFPA 216 is configured to amplify RF signals generated by the second electronic processor 212. The attenuator circuit 112 is communicatively connected between the cellular broadband modem 212 and the cellular RFPA 216 for selectively attenuating the RF signals generated by the cellular broadband modem 212. For example, the attenuator circuit 112 may include a first switch S1 and a second switch S2, controlled by the attenuator control circuit 116, for switchably operating the attenuator circuit 112 in an active mode or a bypass mode.

In the bypass mode (e.g., the configuration illustrated in FIG. 2), RF signals generated by the cellular broadband modem 212 bypass an attenuator device 220 of the attenuator circuit 112, and are output to the cellular RFPA 216 without undergoing attenuation. Accordingly, when the attenuator circuit 112 is in the bypass mode, the LTE transmitter system 108 transmits RF signals at, for example, a maximum transmission power level. The maximum transmission power level may vary according to implementation. The maximum transmission power level may be, for example, 10 decibel milliwatts (dBm), 23 dBm, 30 dBm, or the like.

In the active mode, the switches S1 and S2 are switched such that RF signals generated by the cellular broadband modem 212 pass through the attenuator device 220 of the attenuator circuit 112 and undergo attenuation. Accordingly, when the attenuator circuit 112 is in the active mode, the LTE transmitter system 108 transmits the RF signals at a reduced transmission power level. While the control system 200 is illustrated as including two switches S1 and S2 for switching operation of the attenuator circuit 112 in one of the active mode or the bypass mode, the attenuator circuit 112 may be arranged in another suitable configuration for selectively operating in an active mode or a bypass mode. The attenuator circuit 112 may otherwise be referred to herein as the attenuator 112.

The attenuator control circuit 116 at least includes mode control logic 224 for controlling the attenuator 112 for operation in the active mode or the bypass mode (e.g., by controlling the states of the switches S1 and S2). The mode control logic 224 may otherwise by referred to herein as relay control logic 224. The mode control logic 224 may be implemented as, for example, hardware (e.g., programmable hardware), software, or a combination thereof.

The mode control logic 224 controls operation of the attenuator 112 based on state information received from at least the LMR processor 204. For example, the mode control logic 224 may receive transmission indication (TX) signal from the LMR processor 204 (e.g., from a GPIO pin of the LMR processor 204) indicating whether the LMR transmitter system 104 has an active LMR transmission. The mode control logic 224 may also receive an LMR high power signal from the LMR processor 204 indicating whether a transmission power level of the LMR transmitter system 104 is above a threshold. For example, the LMR transmitter system 104 may transmit RF signals at a lower power level when the converged device 100 is closer to an LMR base station than when the converged device 100 is farther from an LMR base station.

In some examples, the attenuator 112 is configured to attenuate RF signals by a fixed attenuation value (e.g., by 10 dBm, 20 dBm, 25 dBm, 30 dBm, etc.). For example, the mode control logic 224 may be implemented as an AND gate configured to control the attenuator 112 for operation in the active mode when both the TX signal and the LMR high power signal are high.

In other examples, the attenuator 112 is a multi-step, or variable, attenuator 112, and the attenuator control circuit 116 further includes attenuation value control logic 228 configured to control the attenuator 112 to attenuate RF signals at a selected one of a plurality of attenuation values. The attenuation value control logic 228 may be implemented as, for example, hardware (e.g., programmable hardware), software, or a combination thereof. The attenuation value control logic 228 may sample a RF front end (RFFE) data line between the cellular broadband modem 212 and the cellular RFPA 216 in order to determine an intended transmission power level of the LTE transmitter system 108. For example, the LTE transmitter system 108 may transmit RF signals at a lower power level when the converged device 100 is closer to an LTE base station than when the converged device 100 is farther from an LTE base station. Accordingly, the attenuation value control logic 228 may select a lower attenuation value when the LTE transmitter system 108 is not configured for high power transmission as compared to when the LTE transmitter system 108 is configured for high power transmission.

Additionally, in some instances, the mode control logic 224 only controls the attenuator 112 for operation in the active mode during simultaneous high power transmissions of the LMR transmitter system 104 and the LTE transmitter system 108.

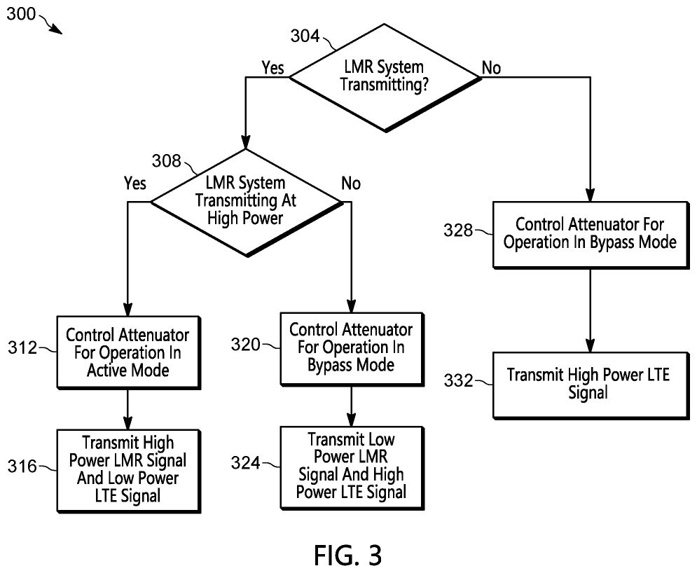

FIG. 3 illustrates an example method 300 for controlling operation of the converged device 100, according to some examples. The method 300 includes determining, with the attenuator control circuit 116 (e.g., the mode control logic 224), whether the LMR transmitter system 104 has an active transmission (at block 304). The mode control logic 224 may determine that the LMR transmitter system 104 has an active transmission responsive to determining that the TX signal received from the LMR processor 204 is high.

In response to determining that the LMR transmitter system 104 has an active transmission (YES at block 304), the attenuator control circuit 116 (e.g., the mode control logic 224) determines whether the LMR transmitter system 104 is transmitting at high power (at block 308). The mode control logic 224 may determine that the LMR transmitter system 104 has an active transmission responsive to determining that the high power transmission signal received from the LMR processor 204 is high.

The LMR processor 204 may output the high power transmission signal (e.g., a logical ‘1’ signal) in response to determining that a transmission power level of the LMR transmitter system 104 is greater than a threshold transmission power level. In contrast, the LMR processor 204 may set the high power transmission signal to be low (e.g., a logical ‘0’ signal) in response to determining that a transmission power level of the LMR transmitter system 104 is not greater than the threshold transmission power level.

The threshold transmission power level for high power transmission may vary according to implementation. For example, the threshold transmission power level may be 1.8 Watts (W), 2 W, 3 W, or the like. The LMR processor 204 derive the transmission power level based on, for example, coverage information associated with the LMR transmitter system 104. In some instances, the threshold transmission power level corresponds to a transmission power level at an edge of a coverage area (e.g., a cell edge) for transmitting LMR signals.

In response to determining that the LMR transmitter system 104 is transmitting at high power (YES at block 308), the attenuator control circuit 116 controls the attenuator 112 for operation in the active mode (at block 312). As described above, in some examples, in the active mode, the attenuator 112 attenuates RF signals generated by the cellular broadband modem 212 by a fixed attenuation value. However, in other examples (e.g., when the attenuator 112 is a variable attenuator 112), the attenuator 112 attenuates the RF signals generated by the cellular broadband modem according to a selected attenuation value received from the attenuator control circuit 116 (e.g., the attenuation value control logic 228).

The attenuation value control logic 228 may select the attenuation value such that the LTE transmitter system 108 transmits the attenuated LTE RF signals at a predetermined dBm level (e.g., 0 dBm, −10 dBm, 10 dBm, etc.) during simultaneous transmissions by the LMR transmitter system 104 and the LTE transmitter system 108. The predetermined dBm level is, for example, a predetermined maximum transmission power level that the LTE transmitter system 108 may transmit at in order to reduce peak current in the converged device 100 during simultaneous transmission with the LMR transmitter system 104. The predetermined dBm level for the LTE transmitter system 108 during simultaneous transmissions may vary according to implementation.

As described above, the attenuation value control logic 228 may sample a data line output from the cellular broadband modem 212 to the cellular RFPA 216, the data line indicating of a gain or transmission power level of the LTE transmitter system 108. The attenuation value control logic 228 may select the attenuation value based on a difference between the transmission power level of the LTE transmitter system 108 (determined based on the sampled data) and the predetermined dBm level for transmission. In other words, the attenuation value may vary in order to transmit at the predetermined dBm level as LTE coverage (e.g., proximity to LTE base stations) of the converged device 100 changes.

As one example, when the LMR transmitter system 104 performs a high power transmission, the predetermined maximum dBm level for the LTE transmitter system 108 is 0 dBm, and the intended transmission power level based on the sampled RFFE data is 23 dBm, the attenuation value control logic 228 may select 23 dBm as the attenuation value. As a result, the attenuator 112 attenuates the 23 dBm RF signal generated by the cellular broadband modem 212 by at least 23 dBm such that the LTE transmitter system 108 transmits the attenuated RF signal at the maximum predetermined dBm level.

The method 300 further includes simultaneously performing high power LMR transmission using the LMR transmitter system 104 and low power (i.e., attenuated) LTE transmission using the LTE transmitter system 108 (at block 316).

In contrast, in response to determining that the LMR transmitter system 104 is not transmitting at high power (NO at block 308), the attenuator control circuit 116 controls the attenuator 112 for operation in the bypass mode (at block 320). As described above, in some examples, the attenuator control circuit 116 controls the attenuator 112 for operation in the bypass mode by controlling (e.g., with the mode control logic 224) the switches S1 and S2 such that the RF signal generated by the cellular broadband modem 212 bypasses the attenuator device 220 in the attenuator circuit 112. Alternatively, or in addition, the attenuator control circuit 116 controls the attenuator 112 for operation in the bypass mode by selecting (e.g., with the attenuation value control logic 228) an attenuation value (e.g., using the attenuation value control logic 228) to be 0 dBm.

The method 300 further includes simultaneously performing the LMR transmission (e.g., the low power LMR transmission) using the LMR transmitter system 104 and high power (i.e., nonattenuated) LTE transmission with the LTE transmitter system 108 (at block 324). In some instances, the high power LTE transmission is an LTE transmission at the maximum transmission power level. However, as described above, the LTE transmission power level may vary according to LTE coverage of the converged device 100. Accordingly, the power level of the high power LTE transmission may differ from the maximum LTE transmission power level, and may vary according to LTE coverage.

Referring again to block 304, in response to determining that the LMR transmitter system 104 does not have an active transmission (NO at block 304), the attenuator control circuit 116 controls the attenuator for operation in the bypass mode (at block 328), and the LTE transmitter system 108 performs high power, nonattenuated LTE transmissions (at block 332).

In the foregoing specification, various examples have been described. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of present teachings. The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

Moreover in this document, relational terms such as first and second, top and bottom, and the like may be used solely to distinguish one entity or action from another entity or action without necessarily requiring or implying any actual such relationship or order between such entities or actions. The terms “comprises,” “comprising,” “has,” “having,” “includes,” “including,” “contains,” “containing,” or any other variation thereof, are intended to cover a non-exclusive inclusion, such that a process, method, article, or apparatus that comprises, has, includes, contains a list of elements does not include only those elements but may include other elements not expressly listed or inherent to such process, method, article, or apparatus. An element proceeded by “comprises . . . a,” “has . . . a,” “includes . . . a,” “contains . . . a” does not, without more constraints, preclude the existence of additional identical elements in the process, method, article, or apparatus that comprises, has, includes, contains the element. Unless the context of their usage unambiguously indicates otherwise, the articles “a,” “an,” and “the” should not be interpreted as meaning “one” or “only one.” Rather these articles should be interpreted as meaning “at least one” or “one or more.” Likewise, when the terms “the” or “said” are used to refer to a noun previously introduced by the indefinite article “a” or “an,” “the” and “said” mean “at least one” or “one or more” unless the usage unambiguously indicates otherwise.

Also, it should be understood that the illustrated components, unless explicitly described to the contrary, may be combined or divided into separate software, firmware, and/or hardware. For example, instead of being located within and performed by a single electronic processor, logic and processing described herein may be distributed among multiple electronic processors. Similarly, one or more memory modules and communication channels or networks may be used even if examples described or illustrated herein have a single such device or element. Also, regardless of how they are combined or divided, hardware and software components may be located on the same computing device or may be distributed among multiple different devices. Accordingly, in this description and in the claims, if an apparatus, method, or system is claimed, for example, as including a controller, control unit, electronic processor, computing device, logic element, module, memory module, communication channel or network, or other element configured in a certain manner, for example, to perform multiple functions, the claim or claim element should be interpreted as meaning one or more of such elements where any one of the one or more elements is configured as claimed, for example, to make any one or more of the recited multiple functions, such that the one or more elements, as a set, perform the multiple functions collectively.

It will be appreciated that some examples may be comprised of one or more generic or specialized processors (or “processing devices) such as microprocessors, digital signal processors, customized processors and field programmable gate arrays (FPGAs) and unique stored program instructions (including both software and firmware) that control the one or more processors to implement, in conjunction with certain non-processor circuits, some, most, or all of the functions of the method and/or apparatus described herein. Alternatively, some or all functions could be implemented by a state machine that has no stored program instructions, or in one or more application specific integrated circuits (ASICs), in which each function or some combinations of certain of the functions are implemented as custom logic. Of course, a combination of the two approaches could be used.

The terms “substantially,” “essentially,” “approximately,” “about” or any other version thereof, are defined as being close to as understood by one of ordinary skill in the art, and in one non-limiting example the term is defined to be within 10%, in another example within 5%, in another example within 1% and in another example within 0.5%. The term “one of,” without a more limiting modifier such as “only one of,” and when applied herein to two or more subsequently defined options such as “one of A and B” should be construed to mean an existence of any one of the options in the list alone (e.g., A alone or B alone) or any combination of two or more of the options in the list (e.g., A and B together).

A device or structure that is “configured” in a certain way is configured in at least that way, but may also be configured in ways that are not listed.

The terms “coupled,” “coupling” or “connected” as used herein can have several different meanings depending on the context in which these terms are used. For example, the terms coupled, coupling, or connected can have a mechanical or electrical connotation. For example, as used herein, the terms coupled, coupling, or connected can indicate that two elements or devices are directly connected to one another or connected to one another through intermediate elements or devices via an electrical element, electrical signal or a mechanical element depending on the particular context.

The Abstract is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various examples for the purpose of streamlining the disclosure. This method of disclosure is not to be interpreted as reflecting an intention that the claimed examples require more features than are expressly recited in each claim. Rather, as the following claims reflect, inventive subject matter lies in less than all features of a single disclosed example. Thus, the following claims are hereby incorporated into the Detailed Description, with each claim standing on its own as a separately claimed subject matter.

What is claimed is:

1. A converged communication device comprising:
a first radio frequency (RF) transmitter system configured to transmit signals according to a first communication protocol, the first RF transmitter system including a first RF power amplifier (RFPA) and a first electronic processor;
a second RF transmitter system configured to transmit signals according to a second communication protocol different from the first communication protocol, the second RF transmitter system including a second RF power amplifier (RFPA) and a second electronic processor;
an attenuator operable in at least an active mode and a bypass mode and configured to receive an RF signal generated by the second electronic processor,
in the bypass mode, provide the RF signal generated by the second electronic processor to the second RFPA, and
in the active mode, attenuate the RF signal generated by the second electronic processor and provide an attenuated RF signal to the second RFPA; and
an attenuator control circuit configured to selectively control the attenuator for operation in the active mode or the bypass mode based on state information received from the first RF transmitter system and/or the second RF transmitter system.

2. The converged communication device of claim 1, wherein attenuation of the RF signal generated by the second RF transmitter system limits a peak current of the converged communication device during simultaneous transmission of the attenuated RF signal and a different RF signal transmitted by the first RF transmitter system.

3. The converged communication device of claim 1, wherein
the attenuator comprises a variable attenuator, and
the attenuation control circuit is configured to select an attenuation value for attenuating the RF signal generated by the second electronic processor and control the attenuator to attenuate the RF signal according to the attenuation value.

4. The converged communication device of claim 3, wherein the attenuation control circuit is configured to select the attenuation value such that the second RF transmitter system transmits the attenuated RF signal at a predetermined decibel milliwatt (dBm) level.

5. The converged communication device of claim 4, wherein
the state information includes an indication of whether the first RF transmitter has an active transmission, and
the attenuation control circuit is configured to control the attenuator for operation in the bypass mode in response to determining, based on the state information, that the first RF transmitter does not have an active transmission.

6. The converged communication device of claim 5, wherein
the state information further includes an indication of high transmission power level of the first transmitter system, and
the attenuation control circuit is configured to control the attenuator for operation in the active mode in response to determining, based on the state information, that the first RF transmitter has an active transmission and that the transmission power level of the first RF transmitter system is greater than a first threshold.

7. The converged communication device of claim 6, wherein the transmission power level of the first RF transmitter system is derived from coverage information associated with the first RF transmitter system.

8. The converged communication device of claim 7, wherein the first threshold corresponds to a transmission power level at an edge of a coverage area for transmitting signals according to first communication protocol.

9. The converged communication device of claim 6, wherein the attenuation control circuit is configured to control the attenuator for operation in the bypass mode in response to determining, based on the state information, that the transmission power level of the first RF transmitter system is not greater than the first threshold.

10. The converged communication device of claim 6, wherein
the state information further includes an indication of high transmission power level of the second RF transmitter, and
the attenuation value is based on a difference between the transmission power level of the second RF transmitter system and the predetermined dBm level.

11. The converged communication device of claim 10, wherein the transmission power level of the second RF transmitter is dependent on a proximity to a base station operating according to the second communication protocol.

12. The converged communication device of claim 10, wherein the attenuation control circuit is configured to determine the transmission power level of the second RF transmitter system by sampling a data line connected between the second electronic processor and the second RFPA.

13. The converged communication device of claim 1, wherein the attenuation control circuit is comprised of programmable hardware.

14. The converged communication device of claim 1, wherein the first communication protocol is a land mobile radio (LMR) communication protocol.

15. The converged communication device of claim 1, wherein the second communication protocol is a wireless broadband communication protocol.

16. A method for controlling a converged communication device having a first radio frequency (RF) transmitter system configured to transmit signals according to a first communication protocol and a second RF transmitter system configured to transmit signals according to a second communication protocol different from the first communication protocol, the method comprising:
selectively controlling, with an attenuator control circuit, an attenuator for operation in at least one of an active mode or a bypass mode based on state information received from the first RF transmitter system and the second RF transmitter system;
receiving, with the attenuator, an RF signal generated by an electronic processor included in the second RF transmitter system;
providing, with the attenuator in the bypass mode, the RF signal generated by the electronic processor to an RF power amplifier (RFPA) included in the second RF transmitter system;
attenuating, with the attenuator in the active mode, the RF signal generated by the electronic processor; and
providing an attenuated RF signal to the RFPA.

17. The method of claim 16, wherein attenuation of the RF signal generated by the second RF transmitter system limits a peak current of the converged communication device during simultaneous transmission of the attenuated RF signal and a different RF signal transmitted by the first RF transmitter system.

18. The method of claim 16, wherein the attenuator comprises a variable attenuator, and the method further comprises:
selecting, with the attenuator control circuit, an attenuation value for attenuating the RF signal generated by the electronic processor; and
controlling the attenuator to attenuate the RF signal according to the attenuation value.

19. The method of claim 18, wherein the attenuation value is selected such that the second RF transmitter system transmits the attenuated RF signal at a predetermined decibel milliwatt (dBm) level.

20. The method of claim 19, wherein the state information includes an indication of whether the first RF transmitter has an active transmission, and the method further comprises:
controlling, with the attenuation control circuit, the attenuator for operation in the bypass mode in response to determining, based on the state information, that the first RF transmitter does not have an active transmission.
